(19) United States
(12) Patent Application Publication
(10) Pub. No.: US 2023/0202765 A1
(43) Pub. Date: Jun. 29, 2023

(54) ARTICLE TRANSFERRING SYSTEM AND WIRELESS NETWORK SENSITIVITY MONITORING METHOD

(71) Applicant: SEMES CO. LTD., Cheonan-si (KR)

(72) Inventors: Jung Dae KIM, Pyeongtaek-si (KR); Man Gyu LEE, Daegu (KR)

(73) Assignee: SEMES CO. LTD., Cheonan-si (KR)

(21) Appl. No.: 18/145,924

(22) Filed: Dec. 23, 2022

(30) Foreign Application Priority Data
Dec. 27, 2021 (KR) 10-2021-0188996
May 27, 2022 (KR) 10-2022-0065221

(51) Int. Cl. B65G 43/00; H04W 24/08; H04W 24/10

(52) U.S. Cl. CPC B65G 43/00; H04W 24/08; H04W 24/10

(57) ABSTRACT

Disclosed is an article transferring system, including: a monitoring device; a transferring vehicle for transferring an article and including a wireless communication unit; a travel rail providing a travel path for the transferring vehicle; and a wireless communication device installed along the travel path, the wireless communication device being configured to form a wireless network in which the transferring vehicle is capable of wirelessly communicating, in which the transferring vehicle is configured to transmit sensitivity data of the transferring vehicle to the wireless network of the wireless communication unit to the monitoring device while traveling along the travel path.

### CROSS-REFERENCE TO RELATED APPLICATIONS

This application claims priority to and the benefit of Korean Patent Application Nos. 10-2021-0188996 and 10-2022-0065221 filed in the Korean Intellectual Property Office on Dec. 27, 2021 and May 27, 2022 the entire contents of which are incorporated herein by reference.

### TECHNICAL FIELD

The present invention relates to an article transferring system and a wireless network sensitivity monitoring method.

### BACKGROUND ART

In general, in order to manufacture a semiconductor device, various types of processes, such as deposition, photography, and etching, are performed, and devices performing each of these processes are arranged in a semiconductor manufacturing line. Articles, such as a substrate (for example, wafer and glass), which are objects to be treated in a semiconductor device manufacturing process, may be provided to each semiconductor treating apparatus in a state of being accommodated in a container, such as a FOUP, POD, tray, magazine, MAGAZINE, cassette. In addition, the articles on which the process has been performed may be recovered from each semiconductor treating apparatus into a container, and the container in which the articles are recovered may be transferred to the outside.

The container is transferred by a transferring vehicle, such as an Overhead Hoist Transport Apparatus (OHT). The transferring vehicle travels along rails provided along the ceiling of the semiconductor manufacturing line. The transferring vehicle transfers the container in which the article is accommodated to a load port of any one of the semiconductor treating devices. In addition, the transferring vehicle may pick up the container in which the processed article is accommodated from the load port and transfer the container to the outside, or transfer the container to another of the semiconductor treating devices.

In general, a transferring vehicle receives a control signal from an overhead hoist transport apparatus control system (OCS) and travels along a rail based on the received control signal. The transferring vehicle receives a control signal related to a transferring destination and loading and unloading of articles from the control system and performs work. In addition, the transferring vehicle may transmit its driving information to the control system. For example, the transferring vehicle may transmit information, such as traveling speed, current position, container holding status, and driving destination, to the control system.

Meanwhile, a wireless Access Point (AP) forming a wireless network is installed in a semiconductor manufacturing line. The transferring vehicle accesses the wireless network formed by wireless APs and exchanges control signals with a control system. In addition, a plurality of wireless APs is installed spaced apart from each other in a semiconductor manufacturing line.

In order for the transferring vehicle to properly receive a control signal from the control system and properly transmit driving information to the control system, the transferring vehicle must have excellent sensitivity to a wireless network. When the signal sensitivity to the wireless network is low, a communication failure may occur between the transferring vehicle and the control system. When the communication failure occurs, problems, such as delay in transferring articles, may occur.

In order to prevent such a problem in advance, signal sensitivity information on the wireless network may be collected by using a portable terminal or a PC having a program capable of measuring signal sensitivity to the wireless network. Workers carry portable terminals or PCs directly. Specifically, a worker collects signal sensitivity information to a wireless network while directly moving an area under a travel rail on which a transferring vehicle moves.

However, in this method of collecting signal sensitivity information, signal sensitivity information for a wireless network is collected under a travel rail, not on a travel rail on which a transferring vehicle actually runs. Accordingly, the collected information differs from the signal sensitivity of the transferring vehicle to the wireless network. In other words, the signal sensitivity information collected from under the travel rail is difficult to be considered as accurate data from the transferring vehicle’s point of view.

Also, in some cases, the line environment may be changed due to movement of a semiconductor treating device in a semiconductor manufacturing line or installation of an interference, such as a partition. When the line environment changes, signal sensitivity of the transferring vehicle to the wireless network may deteriorate in some areas. In order to solve this problem, it is necessary to additionally install a wireless AP or to move and install a wireless AP. However, the collection of signal sensitivity to the wireless network as above is performed when a wireless AP is installed in a semiconductor manufacturing line. That is, collection of signal sensitivity is not continuously performed. Therefore, it is difficult to immediately respond, such as additionally install a wireless AP or move and install the wireless AP.

### SUMMARY OF THE INVENTION

The present invention has been made in an effort to provide an article transferring system and a wireless network sensitivity monitoring method, which are capable of more accurately measuring wireless sensitivity of a transferring vehicle to a wireless network signal.

The present invention has also been made in an effort to provide an article transferring system and a wireless network sensitivity monitoring method, which are capable of easily specifying a region in which wireless sensitivity is weak in a semiconductor manufacturing line.

The present invention has also been made in an effort to provide an article transferring system and a wireless network sensitivity monitoring method which are capable of easily specifying a transferring vehicle in which abnormality has occurred in a wireless communication unit.

The object of the present invention is not limited thereto, and other objects not mentioned will be clearly understood by those of ordinary skill in the art from the following description.

An exemplary embodiment of the present invention provides an article transferring system, including: a monitoring device; a transferring vehicle for transferring an article and including a wireless communication unit; a travel rail providing a travel path for the transferring vehicle; and a wireless communication device installed along the travel path, the wireless communication device being configured to form a wireless network in which the transferring vehicle is capable of wirelessly communicating, in which the transferring vehicle is configured to transmit sensitivity data of the transferring vehicle to the wireless network of the wireless communication unit to the monitoring device while traveling along the travel path.

According to the exemplary embodiment, a plurality of location marks may be marked on the travel path, and the transferring vehicle may be configured to transmit location data of the transferring vehicle obtained by recognizing the location mark to the monitoring device.

According to the exemplary embodiment, the wireless communication device may be provided in plurality and is disposed spaced apart from each other along the travel path, and is assigned with different identification data, and the transferring vehicle may be configured to obtain the identification data of the wireless communication device that formed the wireless network when the wireless communication unit is connected to the wireless network, and transmit the obtained identification data to the monitoring device.

According to the exemplary embodiment, the monitoring device may include: an analysis unit configured to analyze the sensitivity data, the location data, and the identification data; and a display unit configured to display an analysis result of the analysis unit.

According to the exemplary embodiment, the analysis unit may be configured to derive sensitivity to the wireless network at a node of the travel rail at which the location mark is marked based on the location data and the sensitivity data.

According to the exemplary embodiment, the analysis unit may divide the sensitivity to the wireless network of the wireless communication unit into two or more sensitivity grades according to a predetermined reference value, and may be configured to derive a sensitivity grade of the wireless communication unit to the wireless network at a node of the travel rail marked with each of the location marks.

According to the exemplary embodiment, the transferring vehicle may further include a storage unit for storing the sensitivity data, and is configured to obtain the sensitivity data while traveling along the travel path and store the sensitivity data in the storage unit.

According to the exemplary embodiment, the transferring vehicle may be configured to transmit the sensitivity data obtained while traveling along the travel path to the monitoring device in real time.

According to the exemplary embodiment, the article transferring system may further include a control device for transmitting a control signal to the transferring vehicle, in which the transferring vehicle may be configured to transmit the sensitivity data obtained while traveling along the travel path to the monitoring device through the control device.

Another exemplary embodiment of the present invention provides a method of monitoring sensitivity between a wireless communication unit and a wireless network included in a vehicle in a traveling system including a travel rail providing a travel path, a plurality of vehicles traveling along the travel rail, and a plurality of wireless communication devices installed along the travel path and forming wireless networks, respectively, the method including: obtaining, by the vehicle, sensitivity data on sensitivity between the wireless communication unit and the wireless network while the vehicle travels along the travel path. The vehicle may recognize a location mark marked on the travel path and obtain the sensitivity data at the location mark.

According to the exemplary embodiment, the vehicle may recognize a location mark marked on the travel path and obtains identification data of the wireless network connected at the location mark.

According to the exemplary embodiment, the vehicle may transmit the sensitivity data at the location mark and the identification data of the wireless network connected at the location mark to a monitoring device.

According to the exemplary embodiment, the monitoring device may analyze the sensitivity data, the identification data, and the location mark from the vehicle, and displays a analysis result on a display.

According to the exemplary embodiment, the vehicle may transmit the sensitivity data at the location mark and the identification data at the location mark to a monitoring device in real time, in which the monitoring device is a device analyzing received data and enables a user to monitor an analysis result.

According to the exemplary embodiment, the vehicle may transmit the sensitivity data at the location mark and the identification data at the location mark to a monitoring device in real time, in which the monitoring device is a device analyzing received data and enables a user to monitor an analysis result.

According to the exemplary embodiment, the vehicle may store the sensitivity data at the location mark and the identification data at the location mark in a storage unit provided in the vehicle, and then transmit the data stored in the storage unit to a monitoring device, in which the monitoring device is a device analyzing received data and enables a user to monitor an analysis result.

According to the exemplary embodiment, the vehicle may transmit the sensitivity data at the location mark and the identification data at the location mark to a control device that transmits a control signal to the vehicle.

Still another exemplary embodiment of the present invention provides a method of monitoring signal sensitivity of transferring vehicles to a wireless network formed by a wireless communication device installed in a semiconductor manufacturing line, the method including: driving the transferring vehicles along a travel rail installed on a ceiling of a semiconductor manufacturing line; and obtaining, by the transferring vehicle, sensitivity to the wireless network while the transferring vehicles travel along the travel rail.

According to the exemplary embodiment, the method may further include recognizing, by the transferring vehicles, a location mark marked on the travel rail and transmitting the sensitivity at the location mark to a monitoring device.

According to the exemplary embodiment, the method may further include transmitting, by the transferring vehicles, identification data about the wireless communication device connected at the location mark to the monitoring device.

According to the exemplary embodiment of the present invention, it is possible to more accurately measure wireless sensitivity of a transferring vehicle to a wireless network signal.

In addition, according to the exemplary embodiment of the present invention, it is possible to easily specify a region in which wireless sensitivity is weak in a semiconductor manufacturing line.

In addition, according to the exemplary embodiment of the present invention, it is possible to easily specify a transferring vehicle in which abnormality has occurred in a wireless communication unit.

The effect of the present invention is not limited to the foregoing effects, and non-mentioned effects will be clearly understood by those skilled in the art from the present specification and the accompanying drawings.

### BRIEF DESCRIPTION OF THE DRAWINGS

FIG. 1 is a diagram schematically illustrating an article transferring system according to an exemplary embodiment of the present invention.

FIG. 2 is a cross-sectional view of the transferring vehicle of FIG. 1 viewed from the front.

FIG. 3 is a cross-sectional view of the transferring vehicle of FIG. 1 viewed from the side.

FIG. 4 is a diagram schematically illustrating location marks marked on a travel rail of FIG. 1.

FIG. 5 is a diagram schematically illustrating a location where the location mark of FIG. 4 is marked.

FIG. 6 is a block diagram schematically illustrating a monitoring device of FIG. 1.

FIG. 7 is a flowchart schematically illustrating a wireless network sensitivity monitoring method according to an exemplary embodiment of the present invention.

FIG. 8 is a diagram illustrating an example in which an analysis result derived by an analysis unit of FIG. 6 is displayed on a display unit.

FIG. 9 is a diagram illustrating another example in which an analysis result derived by an analysis unit of FIG. 6 is displayed on a display unit.

FIG. 10 is a diagram illustrating another example in which an analysis result derived by an analysis unit of FIG. 6 is displayed on a display unit.

FIG. 11 is a diagram illustrating another example in which an analysis result derived by an analysis unit of FIG. 6 is displayed on a display unit.

FIG. 12 is a diagram illustrating another example in which an analysis result derived by an analysis unit of FIG. 6 is displayed on a display unit.

### DETAILED DESCRIPTION

Hereinafter, an exemplary embodiment of the present invention will be described more fully hereinafter with reference to the accompanying drawings, in which exemplary embodiments of the invention are illustrated. However, the present invention can be variously implemented and is not limited to the following exemplary embodiments. In the following description of the present invention, a detailed description of known functions and configurations incorporated herein is omitted to avoid making the subject matter of the present invention unclear. In addition, the same reference numerals are used throughout the drawings for parts having similar functions and actions.

Unless explicitly described to the contrary, the word “comprise” and variations, such as “comprises” or “comprising” will be understood to imply the inclusion of stated elements but not the exclusion of any other elements. It will be appreciated that terms “including” and “having” are intended to designate the existence of characteristics, numbers, operations, operations, constituent elements, and components described in the specification or a combination thereof, and do not exclude a possibility of the existence or addition of one or more other characteristics, numbers, operations, operations, constituent elements, and components, or a combination thereof in advance.

Singular expressions used herein include plurals expressions unless they have definitely opposite meanings in the context. Accordingly, shapes, sizes, and the like of the elements in the drawing may be exaggerated for clearer description.

Terms, such as first and second, are used for describing various constituent elements, but the constituent elements are not limited by the terms. The terms are used only to discriminate one constituent element from another constituent element. For example, without departing from the scope of the invention, a first constituent element may be named as a second constituent element, and similarly a second constituent element may be named as a first constituent element.

It should be understood that when one constituent element referred to as being “coupled to” or “connected to” another constituent element, one constituent element can be directly coupled to or connected to the other constituent element, but intervening elements may also be present. In contrast, when one constituent element is “directly coupled to” or “directly connected to” another constituent element, it should be understood that there are no intervening element present. Other expressions describing the relationship between the constituent elements, such as “between ~” and “just between ~” or “adjacent to ~” and “directly adjacent to ~” should be interpreted similarly.

All terms used herein including technical or scientific terms have the same meanings as meanings which are generally understood by those skilled in the art unless they are differently defined. Terms defined in generally used dictionary shall be construed that they have meanings matching those in the context of a related art, and shall not be construed in ideal or excessively formal meanings unless they are clearly defined in the present application.

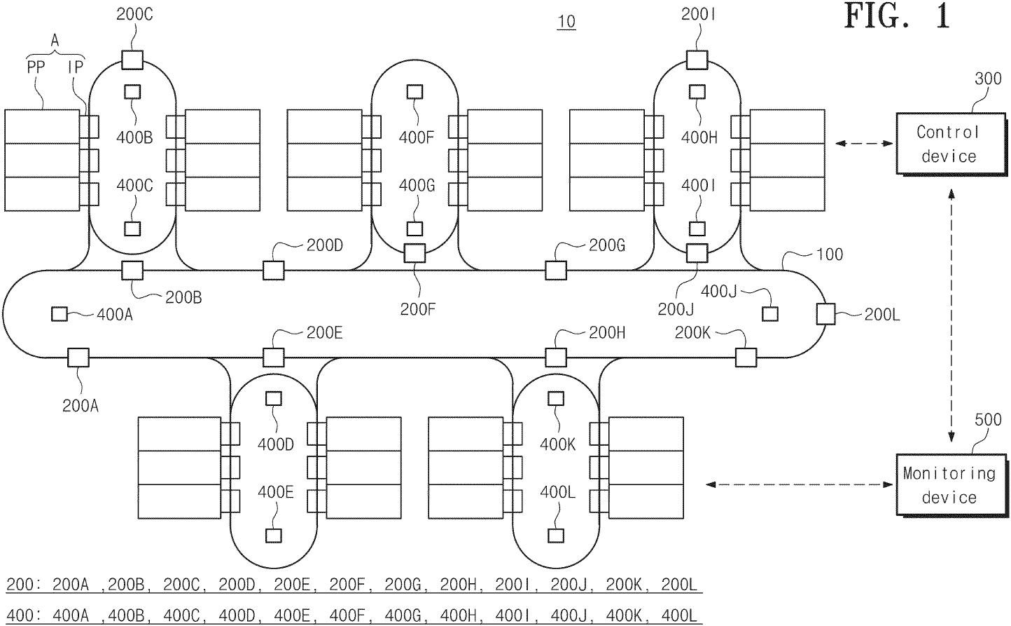

Hereinafter, an article transferring system and a wireless network sensitivity monitoring method according to an exemplary embodiment of the present invention will be described in detail with reference to FIGS. 1 to 12.

FIG. 1 is a diagram schematically illustrating an article transferring system according to an exemplary embodiment of the present invention.

Referring to FIG. 1, the article transferring system 10 of the present exemplary embodiment may be used to transfer a container. In particular, the article transferring system 10 of the present exemplary embodiment may transfer a container in which an article is accommodated. The article may be a substrate, such as a wafer, glass, reticle, or mask. The container in which an article is accommodated may be a Front Opening Unified Pod (FOUP) or a cassette. Further, the container in which an article is accommodated may be a POD. Also, the container in which the article is accommodated may be a magazine for accommodating a plurality of printed circuit boards and a tray for accommodating a plurality of semiconductor packages.

Hereinafter, the present invention will be described based on the case in which the article transferring system 10 transfers a container in which a substrate, such as a wafer, is accommodated to substrate treating apparatuses A arranged in a semiconductor manufacturing line as an example. The article transferred by the article transferring system 10 is described as an example of a substrate used for manufacturing a semiconductor device. However, the present invention it is not limited thereto, and the article transferring system 10 of the present exemplary embodiment may be equally or similarly applied to various manufacturing lines requiring transferring of articles and/or containers containing articles.

In addition, the substrate treating apparatus A in which the article transferring system 10 transfers the article according to the exemplary embodiment of the present invention may perform a treatment process of treating a substrate. For example, the substrate treating apparatus A may be an apparatus capable of performing processes, such as cleaning, etching, ashing, baking, and coating, on a substrate. The substrate treating apparatus A may include an index unit IP and a treating unit PP. The index unit IP may include a load port through which a container containing the above-described article may be loaded or unloaded. An article (for example, a substrate such as a wafer) in the container seated on the index unit IP may be transferred to the treating unit PP of the substrate treating apparatus A that performs a treatment process on the substrate. The treating unit PP may be configured to perform the above-described processes on the substrate.

The article transferring system 10 may include a travel rail 100, a transferring vehicle 200, a control device 300, a wireless communication device 400, and a monitoring device 500.

The travel rail 100 may provide a travel path along which the transferring vehicle 200 travels. The travel rail 100 may be fixed to the ceiling of a semiconductor manufacturing line. The travel rail 100 may be fixed to the ceiling of the semiconductor manufacturing line through a shaft installed on the ceiling of the semiconductor manufacturing line. The travel path provided by the travel rail 100 may be disposed to overlap the substrate treating apparatus A when viewed from above. For example, the travel path provided by the travel rail 100 may be arranged to overlap with the index unit IP of the substrate treating apparatus A when viewed from above. Accordingly, the transferring vehicle 200 to be described later may seat the container in which the article is accommodated in the index unit IP of the substrate treating apparatus A.

The transferring vehicle 200 may travel along the travel rail 100. The transferring vehicle 200 may transfer a container in which an article is accommodated while moving along the travel rail 100. The transferring vehicle 200 may be an overhead transport apparatus (OHT) that travels along the travel rail 100 installed in the semiconductor manufacturing line. The plurality of transferring vehicles 200 may be provided. For example, the article transferring system 10 may include a first transferring vehicle 200A to a twelfth transferring vehicle 200L. The number of transferring vehicles 200 included in the product transferring system 10 may be variously modified according to the design of the semiconductor manufacturing line.

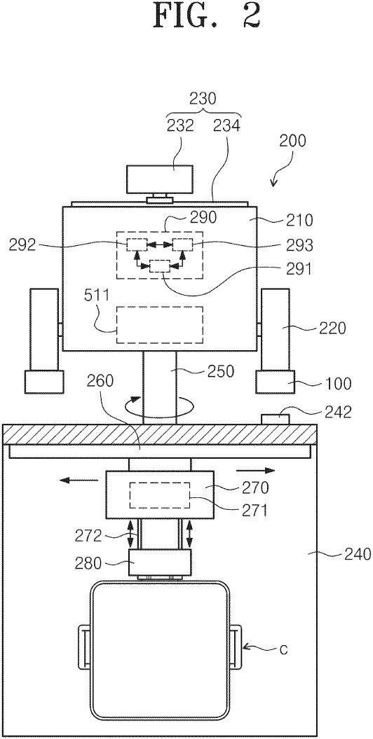

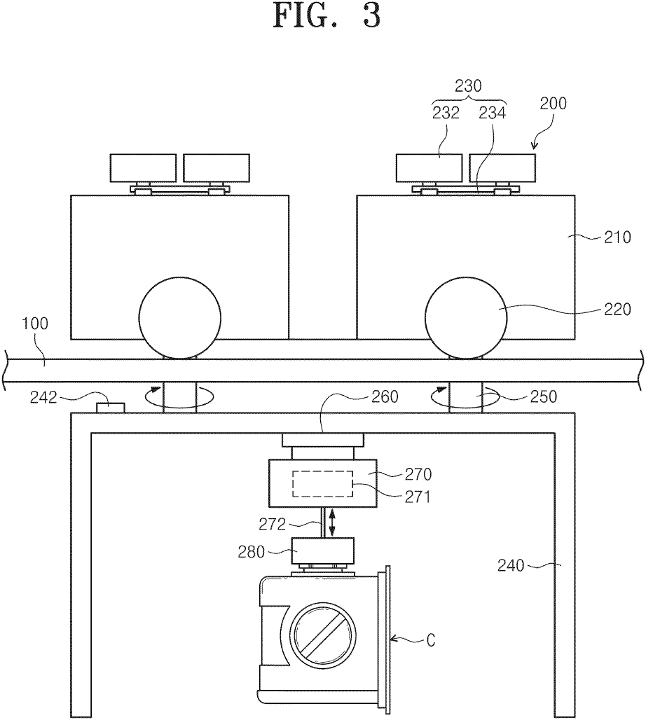

FIG. 2 is a cross-sectional view of the transferring vehicle of FIG. 1 viewed from the front, and FIG. 3 is a cross-sectional view of the transferring vehicle of FIG. 1 viewed from the side.

Referring to FIGS. 2 and 3, the transferring vehicle 200 according to the exemplary embodiment of the present invention may be configured to be able to travel along the travel rail 100 described above. The transferring vehicle 200 may be configured to hold a container C. The transferring vehicle 200 may be configured to travel along the rail 100 while holding the container C. The transferring vehicle 200 may include a body 210, a traveling wheel 220, a steering member 230, a frame 240, a neck 250, a slider 260, a lifting member 270, a grip member 280, and a control unit 290.

The traveling wheel 220, the steering member 230, and the neck 550 may be coupled to the body 210. The traveling wheel 520 may be rotatably coupled to the body 210. In addition, the body 510 may be provided with a traveling driver 211 for rotating the traveling wheel 220. In addition, the body 210 may include a control unit 290 that controls the operation of the transferring vehicle 200. Also, the steering member 230 may be provided on the upper surface of the body 210. In addition, the neck 250 may be rotatably coupled to the body 210.

The traveling driver 211 may transmit power to the traveling wheel 220 to rotate the traveling wheel 220. In addition, a plurality of bodies 510 may be provided. Each body 510 may have the above-described traveling driver 210. In addition, the aforementioned driving wheel 220, steering member 230, and neck 250 may be coupled to each body 210.

The traveling wheel 220 may be rotatably coupled to the body 210. The traveling wheel 220 may be rotated by receiving power from the traveling driver 211. The traveling wheel 220 may be rotated while being in contact with the traveling rail 100. The traveling wheel 220 may be coupled to the body 210. The traveling wheel 220 may be rotatably coupled to the body 210. The traveling wheel 220 may contact the traveling rail 100 and be rotated to travel on the traveling rail 310 A plurality of traveling wheels 220 may be provided. The driving wheels 220 may be provided as a pair. One of the traveling wheels 220 may be rotatably coupled to one surface of the body 210, and the other of the traveling wheels 220 may be rotatably coupled to the other surface opposite to one surface of the body 210.

The steering member 230 may be provided above the body 210. The steering member 230 may include a plurality of steering wheels 232 and a steering rail 234. When viewed from above, the steering wheel 232 may be disposed along a direction parallel to the traveling direction of the transferring vehicle 200. In addition, the steering rail 234 may have a longitudinal direction parallel to a direction perpendicular to the traveling direction of the transferring vehicle 200 when viewed from above. Also, the location of the steering wheel 232 may be changed along the longitudinal direction of the steering rail 234.

The frame 240 may have an inner space. The slider 260, the lifting member 270, and the grip member 280, which will be described later, may be provided in the inner space of the frame 240. In addition, the frame 240 may have a hexahedral shape with both lateral surface and lower surface open. That is, a front surface and a rear surface of the frame 240 may be provided as a blocking plate. Accordingly, it is possible to prevent the container C held from being shaken by air resistance while the transferring vehicle 200 is traveling. In addition, the frame 240 may be coupled to the body 210 via the neck 250. The neck 250 may be rotatably provided with respect to the body 210 and the frame 240. The frame 240 may be coupled to at least one body 210 via at least one neck 250. For example, one frame 240 may be provided, and two necks 250 may be coupled to one frame 240. In addition, the two necks 250 may be coupled to different bodies 210, respectively.

The slider 260 may be coupled to the frame 240. The slider 260 may change the location of the lifting member 270. The slider 260 may move the lifting member 270 in a direction perpendicular to the traveling direction of the transferring vehicle 200. That is, the slider 260 can change the location of the container C gripped by the grip member 280 to the right and left with respect to the traveling direction of the transferring vehicle 200.

The lifting member 270 may be provided between the body 510 and the grip member 280. The lifting member 270 may move the grip member 580 in the vertical direction. The lifting member 270 may move up and down the grip member 280. The lifting member 270 may include a lifting driver 271 and a belt 272. The lifting member 270 may be referred to as a hoist device. The lifting driver 271 may change the length of the suspended belt 271 by winding or unwinding the belt 272. For example, when the lifting driver 271 unwinds the belt 272, the length of the belt 272 may be increased, and when the lifting driver 272 winds the belt 271, the length of the belt 272 may be decreased. In addition, a plurality of belts 272 may be provided. One end of each of the plurality of belts 272 may be connected to the grip member 280.

The grip member 280 may grip the container C. When the grip member 280 is closed, the grip member 280 may grip the container C. When the grip member 280 is opened, the grip member 580 may release the container 20. That is, the grip member 280 may hold the container C in a detachable manner. The grip member 280 may unload the container C from the index unit IP of the substrate treating apparatus A.

The control unit 290 may be provided on the body 210 as described above. The control unit 290 may be provided in an inner space of the body 210. The control unit 290 may control at least one of the configurations of the transferring vehicle 200, for example, the traveling driver 211, the lift driver 271, and the slider 260. The control unit 290 may include a wireless communication unit 291, a storage unit 292, and a control unit 293.

The wireless communication unit 291 may access a wireless network formed by the wireless communication device 400 to be described later. Accordingly, the transferring vehicle 200 may be capable of wirelessly communicating with the control device 300 and/or the monitoring device 500 to be described later. The wireless communication unit 291 may include a wireless LAN card. In addition, the wireless communication unit 291 may receive a control signal from the control device 300 to be described later via a wireless network formed by the wireless communication device 400 and transmit the received control signal to the control unit 293.

The control signal transmitted by the control device 300 may include the traveling speed and the driving destination of the transferring vehicle 200, whether the container C is being held, whether the container C is loaded/unloaded, and the like. The control unit 293 may control the operation of the transferring vehicle 200 based on the control signal transmitted from the control device 300. The control unit 293 may include a processor that performs calculations for controlling the configurations of the transferring vehicle 200. The processor may consist of one or more processing circuits for arithmetic calculation and signal processing.

The storage unit 292 may store information about the transferring vehicle 200, commands for controlling the transferring vehicle 200, and the like. Also, the storage unit 292 may store driving information of the transferring vehicle 200. Also, the storage unit 292 may temporarily store driving information of the transferring vehicle 200. The temporarily stored driving information may be transmitted to the control device 300 and/or the monitoring device 500 to be described later in real time through the wireless communication unit 291. For example, the storage unit 292 may include a volatile memory. Also, the storage unit 292 may permanently store driving information of the transferring vehicle 200. The permanently stored driving information may be transmitted to the control device 300 and/or the monitoring device 500 through a wireless or wired communication method. For example, the storage unit 292 may include a non-volatile memory.

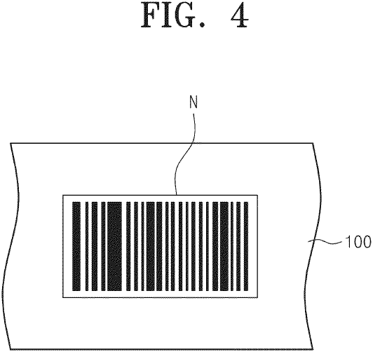

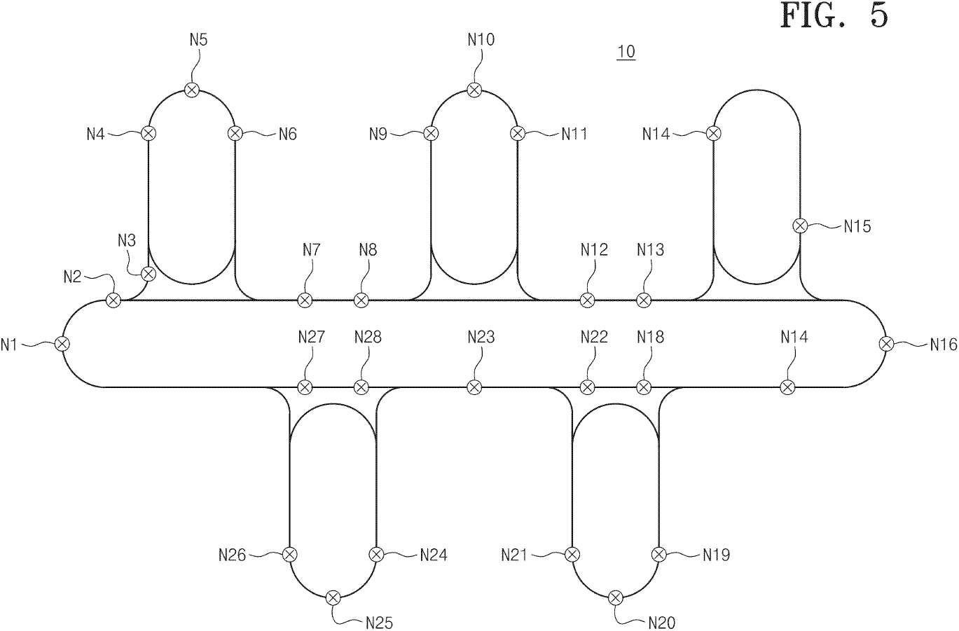

The transferring vehicle 200 may further include a recognition unit 242. The recognition unit 242 may be a substrate capable of recognizing a location mark N marked on the travel rail 100 as illustrated in FIG. 4. The recognition unit 242 may be a camera capable of recognizing the location mark N marked on the travel rail 100 or a barcode recognition device. When the recognition unit 242 recognizes the location mark N, the control unit 290 may derive location data described below, that is, the current location of the transferring vehicle 200. For example, the location mark N is formed on the travel rail 100, and as illustrated in FIG. 5, a plurality of location marks N may be formed on the travel rail 100. For example, the location mark N formed on the travel rail 100 may include a first location mark N1 to a 28th location mark N28. However, this is only an example and the number of location marks N formed on the travel rail 100 may be variously modified as needed.

The driving information of the transferring vehicle 200 that the transferring vehicle 200 may transmit to the control device 300 and/or the monitoring device 500 may include a travel speed of the transferring vehicle 200 (hereinafter referred to as “speed data”), a location of the transferring vehicle 200 (hereinafter referred to as “location data”), sensitivity to the wireless network of the transferring vehicle 200 (hereinafter referred to as “sensitivity data”), and identification information on the wireless communication device 400 forming the wireless network to which the transferring vehicle 200 is connected (hereinafter referred to as “identification data”).

The location data may be data related to the current location of the transferring vehicle 200. The location data may be collected by recognizing the location mark N marked on the traveling rail 100 by the recognition unit 242 of the transferring vehicle 200. The location mark N may be a mark, such as a barcode or a QR code, including information about where the location mark N is marked on the running rail 100. When the recognition unit 242 recognizes the corresponding mark, the control unit 290 may estimate the current location of the transferring vehicle 200.

The identification data may be identification information about the wireless communication device 400 to be described later. A plurality of wireless communication devices 400 may be provided, and assigned with identification information to distinguish the wireless communication devices 400 from each other. The identification data may be the Mac Address, S/N, and the like of the connected wireless communication device 400. The identification data may be collected by connecting the wireless communication unit 291 to the wireless communication device 400 to be described later.

The sensitivity data may be collected by measuring, by the control unit 290, the signal sensitivity of the wireless communication unit 291 to the wireless network at set intervals. For example, the sensitivity data may be collected by measuring the signal sensitivity of the wireless communication unit 291 to the wireless network at predetermined time intervals (for example, 1 second interval).

Referring back to FIG. 1, the control device 300 may control the article transferring system 10. The control device 300 may control the transferring vehicle 200. The control device 300 may control the transferring vehicles 200. The control device 300 may control the transferring vehicles 200 to transfer containers containing articles to the substrate treating devices A disposed in the semiconductor manufacturing line. The control device 300 may control traveling of the transferring vehicles 200. The control device 300 may transmit a control signal (command) for controlling the transferring vehicles 200 to the transferring vehicle 200. The control device 300 may be connected to the transferring vehicles 200 through a wireless communication method. According to the control signal (command) of the control device 300, the transferring vehicles 200 may transfer the goods from a starting location instructed by the control device 300 to a destination location.

The control device 300 may include a process controller formed of a microprocessor (computer) that executes the control of the article transferring system 100, a user interface formed of a keyboard in which an operator performs a command input operation or the like in order to manage the article transferring system 100, a display for visualizing and displaying an operation situation of the article transferring system 100, and the like, and a storage unit storing a control program for executing the process executed in the article transferring system 100 under the control of the process controller. Further, the user interface and the storage unit may be connected to the process controller. The treating recipe may be stored in a storage medium in the storage unit, and the storage medium may be a hard disk, and may also be a portable disk, such as a CD-ROM or a DVD, or a semiconductor memory, such as a flash memory.

The wireless communication device 400 may form a wireless network. The wireless network formed by the wireless communication device 400 may allow the transferring vehicle 200 to communicate wirelessly with the control device 300 and/or the monitoring device 500. The wireless communication device 400 may be a wireless access point (AP). The wireless communication device 400 may be a wireless router. A plurality of wireless communication devices 400 may be provided. For example, the wireless communication device 400 may include a first wireless communication device 400A to a twelfth wireless communication device 400L. However, this is just one example, and the number of wireless communication devices 400 may be variously modified to the number that can cover all areas in which the transferring vehicle 200 travels.

In addition, different identification data are assigned to the wireless communication devices 400. For example, the first wireless communication device 400A may have a first address designated as a Mac address and a first number designated as an S/N. The second wireless communication device 400B may have a first address designated as a Mac address and a second number designated as an S/N. The first address and the second address may be different from each other. The first number and the second number may be different from each other.

The wireless communication devices 400 may be installed apart from each other along the travel path provided by the travel rail 100 on which the transferring vehicle 200 travels. Each of the wireless communication devices 400 may form a wireless network within a set area. While the transferring vehicle 200 travels along the travel rail 100, the transferring vehicle 200 may access a wireless network formed by the wireless communication device 400 having the highest signal sensitivity to the wireless network. For example, the first transferring vehicle 200A may access the wireless network formed by the first wireless communication device 400A while the first transferring vehicle 200A passes through the first area, and the first transferring vehicle 200A may access a wireless network formed by the second wireless communication device 400B while the first transferring vehicle 200A passes through a second area different from the first area. In this way, the wireless communication devices 400 may be installed at appropriate locations of the semiconductor manufacturing line so that the transferring vehicle 200 may wirelessly communicate with the control device 300 without communication failure.

The monitoring device 500 may be configured to monitor driving information of the transferring vehicle 200. The monitoring device 500 may be configured to enable a user to monitor sensitivity data, location data, and identification data among the driving information of the transferring vehicle 200. The monitoring device 500 may analyze driving information of the transferring vehicle 200 transmitted from the transferring vehicle 200 through the wireless network.

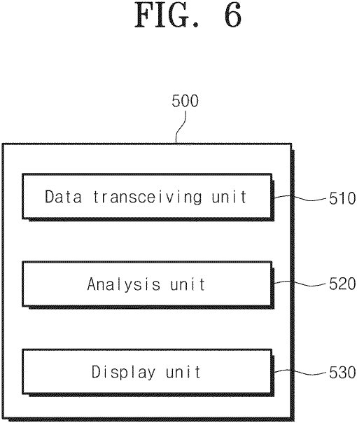

FIG. 6 is a block diagram schematically illustrating the monitoring device of FIG. 1.

Referring to FIG. 6, the monitoring device 500 may include a data transceiving unit 510, an analysis unit 520, and a display unit 530. The data transceiving unit 510 may be configured to transceive the driving information of the transferring vehicle 200 wirelessly or wired. The data transceiving unit 510 may be configured to transceive data to and from the control device 300 wirelessly or wired. The data transceiving unit 510 may include a volatile or non-volatile memory capable of storing data.

The analysis unit 520 may analyze the driving information of the transferring vehicle 200 transmitted to the data transceiver 510. The analysis unit 520 may be configured to analyze the above-described sensitivity data, location data, and identification data. The analysis unit 520 may include a processor that performs an operation of analyzing driving information. The analysis unit 520 may include a memory in which a program capable of analyzing driving information is stored.

The display unit 530 may be configured to display analysis results analyzed by the analysis unit 520. The display unit 530 may be configured to allow a user to recognize the analysis result analyzed by the analysis unit 520. The display unit 530 may include a display.

Hereinafter, a method for monitoring the sensitivity between the transferring vehicle 200 and the wireless communication device 400 according to an exemplary embodiment of the present invention will be described in detail.

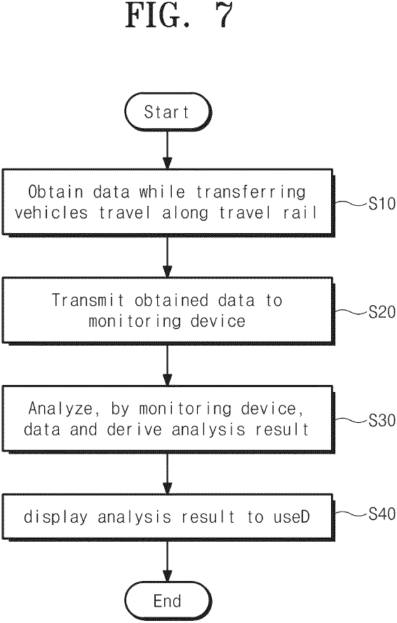

FIG. 7 is a flowchart schematically illustrating a wireless network sensitivity monitoring method according to an exemplary embodiment of the present invention.

Referring to FIGS. 1, 5 and 7, the transferring vehicles 200 may travel along the travel rail 100. The transferring vehicles 200 may obtain data about their own driving information while traveling along the travel rail 100. The transferring vehicles 200 may collect driving information including location data, sensitivity data, and identification data while traveling along the travel path provided by the traveling rail 100.

For example, in a first operation S10, the first transferring vehicle 200A may recognize the location marks N marked on the travel rail 100 while moving along the travel rail 100. When the first transferring vehicle 200A recognizes the first location mark N1, the first transferring vehicle 200A may recognize that its own location is the location where the first location mark N1 is marked on the traveling rail 100. In this case, the first transferring vehicle 200A may collect data about the kind of device among the wireless communication devices 400 forming the wireless network accessed by the first transferring vehicle 200A, and the signal sensitivity to the wireless network. In short, when the first transferring vehicle 200A recognizes the first location mark N1, the first transferring vehicle 200A may collect identification data and measure sensitivity data at the first location mark N1. When the first transferring vehicle 200A moves and recognizes the second location mark N2, the first transferring vehicle 200A may measure identification data and sensitivity data at the second location mark N2. Such data acquisition may be continuously performed while the first transferring vehicle 200A travels along the travel path provided by the travel rail 100. In addition, such data acquisition may be performed not only by the first transferring vehicle 200A, but also by another transferring vehicle 200 traveling along the travel rail 100.

In a second operation S20, each of the transferring vehicles 200 may transmit the collected data to the monitoring device 500. The data collected by the transferring vehicles 200 may be transmitted to the monitoring device 500 in real time.

In a third operation S30, the monitoring device 500 may analyze the received data, for example, the data including the driving information transmitted by the transferring vehicle 200. In the third operation S30, the analysis unit 520 of the monitoring device 500 may analyze the data.

In a fourth operation S40, the analysis unit 520 of the monitoring device 500 may display the result of analyzing the data on the display of the display unit 530.

Hereinafter, the examples of the analysis result obtained by analyzing, by the analysis unit 520, the data and the display of the analysis result on the display unit 530 will be described in detail.

The transferring vehicles 200 collect location data by recognizing the location marks N while traveling along the travel rail 100. In addition, the transferring vehicles 200 recognize the location mark N, and collect sensitivity data and identification data when the transferring vehicles 200 has recognized the location mark N.

That is, the transferring vehicles 200 may collect data about which wireless communication device 400 is connected to at the location where each location mark N is marked (hereinafter, referred to as a “node”), and about the sensitivity to the wireless network formed by the wireless communication device 400.

For example, at the first node where the first location mark N1 is marked, the first transferring vehicle 200A collects the Mac Address and S/N of the first wireless communication device 400A, and measures a he sensitivity value for the wireless network formed by the first wireless communication device 400A. Further, at the first node where the first location mark N1 is marked, the second transferring vehicle 200B may collect the Mac Address and S/N of the first wireless communication device 400A, and the measure a sensitivity value for the wireless network formed by the first wireless communication device 400A. By repeating the process, when the transferring vehicle 200 is located at the first node, the transferring vehicle 200 may access a wireless network of a certain wireless communication device 400 and collect data about a sensitivity value of the signal. These data may be accumulated, which may be similarly performed at each of the location marks N marked on the travel rail 100.

The analysis unit 520 may classify the sensitivity data (measurement values) collected for each of the location marks N into two or more sensitivity grades according to a predetermined reference value. Table 1 below shows examples of grades set for sensitivity measurement values for the wireless network of the wireless communication unit 291. In Table 1, the higher the grade (that is, closer to the 5th grade), the better the sensitivity.

TABLE 1

| Reference value (dbm) | Grade |
|---|---|
| -80 dbm < Measurement value | 5 |
| -90 dbm < Measurement value ≤ - 80 dbm | 4 |
| -100 dbm < Measurement value ≤ -90 dbm | 3 |
| -110 dbm < Measurement value ≤ -100 dbm | 2 |
| -120 dbm < Measurement value ≤ -110 dbm | 1 |

That is, the analysis unit 520 may rank each of the sensitivity data collected by the transferring vehicle 200 at each location mark N. When a plurality of sensitivity data is collected for each location mark N, the analysis unit 520 may rank each of these sensitivity data, and obtain a sensitivity grade at a corresponding node through an average value of the grades. For example, when the sensitivity measurement value obtained by the first transferring vehicle 200A at the first location mark N1 is -75 dbm, the level of the corresponding sensitivity data may be a grade 5. In addition, when the measured sensitivity value obtained by the second transferring vehicle 200B at the first location mark N1 is -85 dbm, the grade for the corresponding sensitivity data may be a grade 4. In this case, the analysis unit 520 may analyze that the sensitivity grade is 4.5 at the first node where the first location mark N1 is marked.

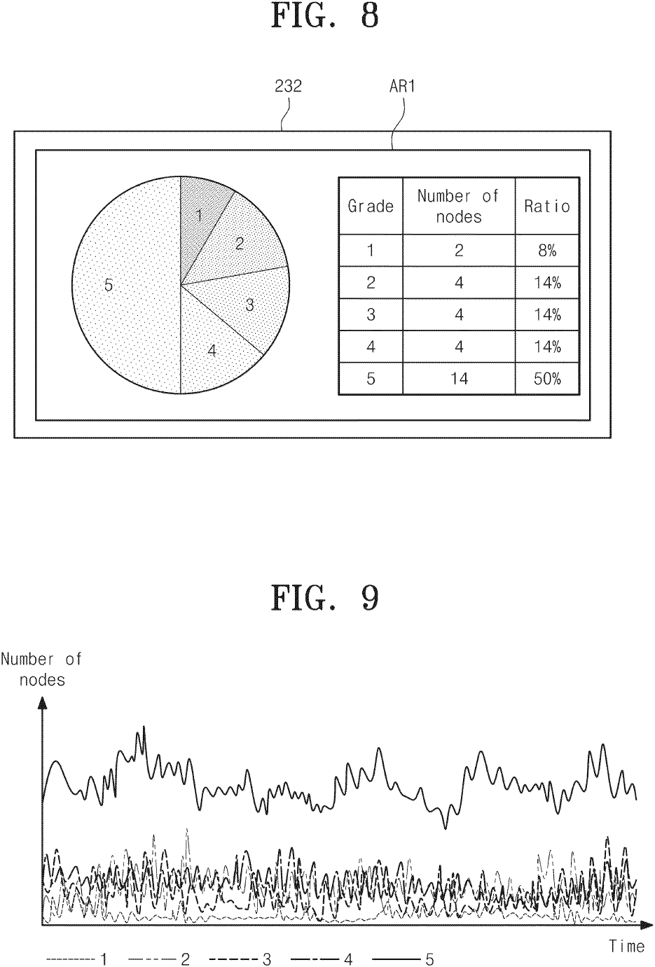

FIG. 8 is a diagram illustrating an example in which an analysis result derived by the analysis unit of FIG. 6 is displayed on the display unit. A first analysis result AR1 includes information about the distribution of the number of nodes for sensitivity grades, and the display unit 530 displays the information in a tables and a graph. That is, the first analysis result AR1 may include information on the number of nodes with a sensitivity grade of 5, the number of nodes with a sensitivity grade of 4, the number of nodes with a sensitivity grade of 3, the number of nodes with a sensitivity grade of 2, and the number of nodes with a sensitivity grade of 1.

FIG. 9 is a diagram illustrating another example in which an analysis result derived by the analysis unit of FIG. 6 is displayed on the display unit. A second analysis result AR2 includes information on changes in the number of nodes having each sensitivity grade over time, and the display unit 530 displays the related information as a graph.

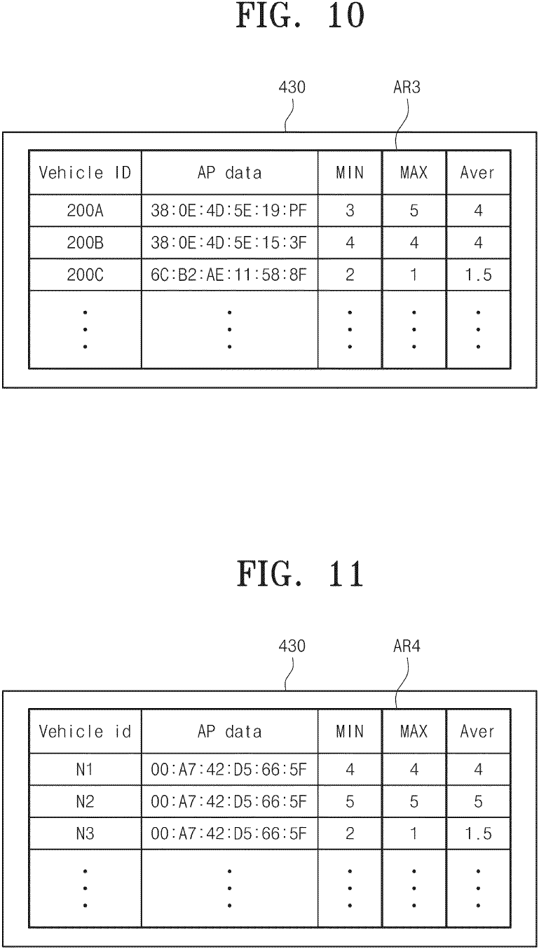

FIG. 10 is a diagram illustrating another example in which an analysis result derived by the analysis unit of FIG. 6 is displayed on the display unit. A third analysis result AR3 may include information about identification data (which can be referred to as AP data) of the wireless communication device 400 to which each transferring vehicle 200 is currently connected, the minimum value of the sensitivity grade, the maximum value of the sensitivity grade, obtained while each transferring vehicle 200 is traveling, and an average value of obtained sensitivity grades. Through the third analysis result AR3, the user may specify the transferring vehicle 200 whose sensitivity grade is consistently low, and in this case, it may be estimated that a problem has occurred in the wireless communication unit 291 of the transferring vehicle 200.

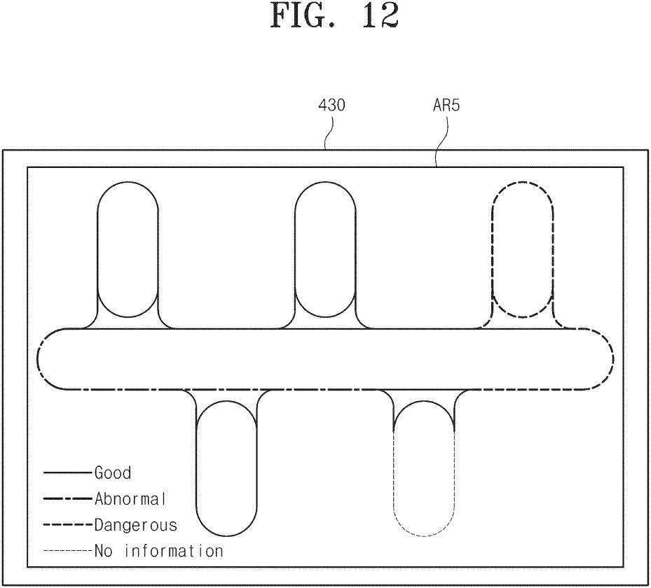

FIG. 11 is a diagram illustrating another example in which the analysis result derived by the analysis unit of FIG. 6 is displayed on the display unit. A fourth analysis result AR4 may include information about identification data (which can be referred to as AP data) of the connected wireless communication device 400 when the transferring vehicle 200 is located at each node, the minimum value of the sensitivity grade and the maximum value of the sensitivity grade at each node, and an average value of obtained sensitivity grades. Through the fourth analysis result AR4, the user may specify a node whose sensitivity level is consistently low, and in this case, it may be estimated that a problem has occurred in the location, and the LAN card, and the like of the wireless communication device 400 forming the wireless network at the corresponding node.

FIG. 11 is a diagram illustrating another example in which the analysis result derived by the analysis unit of FIG. 6 is displayed on the display unit. In a fifth analysis result AR5, based on the sensitivity grade values for the respective nodes, a user may check that which area has a good signal sensitivity state, whether the signal sensitivity is abnormal, the signal sensitivity state is dangerous, and whether there is no information about the signal sensitivity in the layout of the travel rail 100.

According to the exemplary embodiment of the present invention, since the transferring vehicle 200 directly measures the received signal sensitivity of the wireless network on the running rail 100 while the transferring vehicle 200 directly travels along the travel rail 100 and while the transferring vehicle 200 travels at the same speed as the actual moving speed, there is an advantage in that it is possible to obtain more accurate sensitivity data, compared to the case where the user measures the signal sensitivity while carrying and moving the PC for measurement below the traveling rail 100.

The foregoing detailed description illustrates the present invention. Further, the above content illustrates and describes the exemplary embodiment of the present invention, and the present invention can be used in various other combinations, modifications, and environments. That is, the foregoing content may be modified or corrected within the scope of the concept of the invention disclosed in the present specification, the scope equivalent to that of the disclosure, and/or the scope of the skill or knowledge in the art. The foregoing exemplary embodiment describes the best state for implementing the technical spirit of the present invention, and various changes required in the specific application field and use of the present invention are possible. Accordingly, the detailed description of the invention above is not intended to limit the invention to the disclosed exemplary embodiment. Further, the accompanying claims should be construed to include other exemplary embodiments as well.

1. An article transferring system, comprising:
a monitoring device;
a transferring vehicle for transferring an article and including a wireless communication unit;
a travel rail providing a travel path for the transferring vehicle; and
a wireless communication device installed along the travel path, the wireless communication device being configured to form a wireless network in which the transferring vehicle is capable of wirelessly communicating,
wherein the transferring vehicle is configured to transmit sensitivity data of the transferring vehicle to the wireless network of the wireless communication unit to the monitoring device while traveling along the travel path.

2. The article transferring system of claim 1, wherein a plurality of location marks is marked on the travel path, and
the transferring vehicle is configured to transmit location data of the transferring vehicle obtained by recognizing the location mark to the monitoring device.

3. The article transferring system of claim 2, wherein the wireless communication device is provided in plurality and is disposed spaced apart from each other along the travel path, and is assigned with different identification data, and
the transferring vehicle is configured to obtain the identification data of the wireless communication device that formed the wireless network when the wireless communication unit is connected to the wireless network, and transmit the obtained identification data to the monitoring device.

4. The article transferring system of claim 3, wherein the monitoring device includes:
an analysis unit configured to analyze the sensitivity data, the location data, and the identification data; and
a display unit configured to display an analysis result of the analysis unit.

5. The article transferring system of claim 4, wherein the analysis unit is configured to derive sensitivity to the wireless network at a node of the travel rail at which the location mark is marked based on the location data and the sensitivity data.

6. The article transferring system of claim 4, wherein the analysis unit divides the sensitivity to the wireless network of the wireless communication unit into two or more sensitivity grades according to a predetermined reference value, and is configured to derive a sensitivity grade of the wireless communication unit to the wireless network at a node of the travel rail marked with each of the location marks.

7. The article transferring system of claim 1, wherein the transferring vehicle further includes a storage unit for storing the sensitivity data, and is configured to obtain the sensitivity data while traveling along the travel path and store the sensitivity data in the storage unit.

8. The article transferring system of claim 1, wherein the transferring vehicle is configured to transmit the sensitivity data obtained while traveling along the travel path to the monitoring device in real time.

9. The article transferring system of claim 1, further comprising:
a control device for transmitting a control signal to the transferring vehicle,
wherein the transferring vehicle is configured to transmit the sensitivity data obtained while traveling along the travel path to the monitoring device through the control device.

10 - 20. (canceled)
